(19) United States
(12) Patent Application Publication
(10) Pub. No.: US 2005/0066902 A1
(43) Pub. Date: Mar. 31, 2005

(54) Method and apparatus for plasma processing

(75) Inventor: Steven T. Fink, Mesa, AZ (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/823,724

(22) Filed: Apr. 14, 2004

Related U.S. Application Data
(60) Provisional application No. 60/505,849, filed on Sep. 26, 2003.

(51) Int. Cl. C23C 16/00

(52) U.S. Cl. 118/729; 118/728

(57) ABSTRACT

A plasma reactor including a process chamber, a holding structure constructed arranged to hold a plasma source assembly and a support structure constructed and arranged to support a chuck assembly. The holding structure at least partially constitutes a wall of said vacuum chamber. The support structure supporting or holding the chuck assembly can be coupled to a lift mechanism which can raise or lower the chuck assembly relative to the plasma source assembly. The lift mechanism can be disposed above or below the process chamber.

This non-provisional application claims the benefit of U.S. provisional application No. 60/505,849, filed Sep. 26, 2003, the contents of which are incorporated in their entirety herein by reference.

### FIELD OF THE INVENTION

The present invention pertains to plasma processing systems and in particular to plasma reactors.

### BACKGROUND OF THE INVENTION

Plasma processing systems are used in the manufacture and processing of semiconductors, integrated circuits, displays and other devices and materials, to remove material from or to deposit material on a substrate such as a semiconductor substrate. In some instances, these plasma processing systems use electrodes for providing RF energy to a plasma useful for depositing on or removing material from a substrate.

There are several different kinds of plasma processes used during wafer or substrate processing. These processes include, for example: plasma etching, plasma deposition, plasma assisted photoresist stripping and in-situ plasma chamber cleaning.

Plasma processing systems often operate with a blend of gasses which must flow through a processing chamber. A pumping system is employed to remove gasses from the processing system.

### BRIEF SUMMARY OF THE INVENTION

An aspect of the present invention is to provide a plasma reactor including a vacuum chamber, a holding structure constructed and arranged to hold a plasma source assembly and a support structure constructed and arranged to support a chuck assembly. The holding structure at least partially constitutes a wall of said vacuum chamber. The support structure is constructed and arranged to raise and lower the chuck assembly relative to the plasma source assembly. The plasma source can be of any type, for example, a capacitively coupled plasma (CCP) source, an inductively coupled plasma (ICP) source, a transformer coupled plasma (TCP) source, an electrostatically shielded radio frequency (ESRF) plasma source, etc.

The holding structure can be made to pivot around a pivot point relative to a wall of the vacuum chamber thus opening up to the inside of the vacuum chamber. The support structure supporting or holding the chuck assembly may be coupled to a lift mechanism which can raise or lower the chuck assembly relative to the plasma source assembly. The lift mechanism can be disposed above or below the chuck assembly.

Another aspect of the invention is to provide a method for varying the space between a plasma source assembly and a chuck assembly, the plasma source assembly being held by a holding structure and the chuck assembly being held by a support structure, the method includes raising or lowering the chuck assembly relative to the plasma source assembly by using a lift mechanism, the lift mechanism being coupled to the support structure.

### BRIEF DESCRIPTION OF THE DRAWINGS

In the accompanying drawings:

FIG. 1 is a cross-sectional view of a plasma reactor, according to an embodiment of the present invention, showing a holding structure holding a capacitively coupled plasma (CCP) source assembly, and an electrode impedance match network;

FIG. 2 is a top view of the plasma reactor according to the embodiment shown in FIG. 1;

FIG. 3 is a cross-sectional detail of a utility via assembly for RF connection to a chuck assembly;

FIG. 4 is a cross-sectional view of another embodiment of the present invention showing a pivotable holding structure relative to a wall of the plasma process chamber;

FIG. 5 is a cross-sectional view of the plasma reactor according to another embodiment of the present invention where the chuck assembly is supported by a plurality of structures comprising bellows assemblies coupled to a lift mechanism provided beneath the process chamber; and

FIG. 6 is a cross-sectional view of a plasma reactor according to yet another embodiment of the present invention where the lift mechanism for the chuck assembly is provided above the process chamber.

### DETAILED DESCRIPTION OF SEVERAL EMBODIMENTS OF THE INVENTION

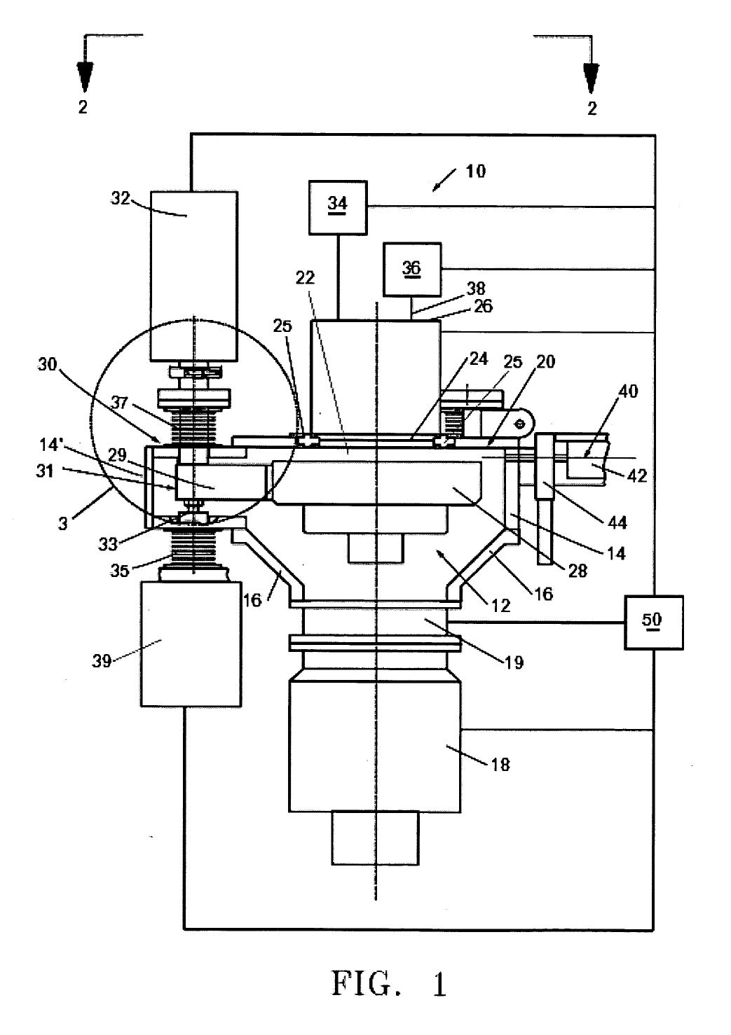

Referring now to FIG. 1, a plasma reactor 10 is shown to include a plasma chamber 12 that functions as a vacuum processing chamber adapted to perform plasma etching from and/or material deposition on a workpiece (not shown). The workpiece can be, for example, a semiconductor substrate or wafer such as silicon. However, other types of substrates are also within the scope of the present invention. Chamber 12 includes sidewall(s) 14, and chamber adapter 16 for connecting vacuum pump 18 to chamber 12. Vacuum pump 18 can be, for example, a turbo-molecular pump (TMP) configured to evacuate process gases from chamber 12. Vacuum pump can be isolated from chamber 12 using gate valve 19.

Plasma reactor 10 also includes holding structure 20. Holding structure 20 supports both electrode assembly 24 and associated electrode impedance match network 26. Insulator(s) 25 are provided to electrically decouple the electrode assembly 24 from the portion of the holding structure which comes in contact with the walls of chamber 12 (electrically grounded). The electrode assembly 24 is arranged adjacent chuck assembly 28 to form plasma processing region 22. Chuck assembly 28 is supported by support structure 30 (described in detail below) which also supports chuck impedance match network 32.

The workpiece support or chuck assembly 28 supports a workpiece while it is processed in chamber 12. In this embodiment, electrode assembly 24 is capacitively coupled to the plasma when the workpiece is being plasma processed, i.e. a capacitively coupled plasma (CCP) source assembly is used in plasma reactor 10. The plasma is formed in plasma processing region 22. The plasma may have a plasma density (i.e., number of ions/volume, along with energy/ion) that is uniform, unless the density needs to be tailored to account for other sources of process non-uniformities or to achieve a desired process non-uniformity. A cooling system in fluid communication with electrode assembly 24 can be included for flowing a cooling fluid to and from the electrode assembly 24.

In this embodiment, although the plasma source used is a capacitively coupled plasma (CCP) source. One of ordinary skill in the art would appreciate that the use of other types of plasma sources such as, but not limited to, an inductively coupled plasma (ICP) source, a transformer coupled plasma (TCP) source, an electrostatically shielded radio frequency (ESRF) plasma source, an electron cyclotron resonance (ECR) plasma source, a helicon plasma source, etc. are also within the scope of the present invention. For example, in ICP, ESRF, and TCP sources an inductive coil is used instead of an electrode assembly as in the case of a CCP source. The inductive coil may be, for example, wound in a spiral configuration proximate or in the vicinity of the chuck assembly.

Electrode assembly 24 may be electrically connected to an RF power supply system 34 via impedance match network 26. The impedance match network matches the impedance of power supply system 34 to the impedance of the electrode assembly 24 and the associated excited plasma. In this way, the power may be delivered by the RF power supply to the plasma electrode assembly 24 and the associated excited plasma with reduced reflection.

In addition, the chuck assembly 28 used to support the workpiece, substrate or wafer can also be provided with an RF power supply coupled thereto to bias the wafer. Similarly to the electrode assembly, the RF bias can be applied to wafer chuck assembly through chuck impedance match network 32. A utility via assembly 31 (described in more detail below) is provided along with the support structure 30 (described also in more detail below). The utility via assembly 31 is constructed and arranged to provide RF connection to chuck assembly 28. Other utilities can also be provided through the same via assembly 31 or through other accesses to the chuck assembly 28 as will be described in the following paragraphs. Such utilities can include cooling systems and/or temperature regulation systems, for example.

The support structure 30 comprises support mechanism 33 constructed and arranged to support chuck assembly 28 via holding arm 29, and an actuation assembly not shown. The support mechanism 33 is coupled, through external bellows assembly 35, to the actuation assembly 39 (such as a lift mechanism) for moving, e.g., for raising and lowering the chuck assembly 28. In this way, for example, the space between the chuck assembly 28 and the electrode assembly 24 can be increased or decreased according to desired parameters of the plasma process.

For facilitating access to support mechanism 33 an opening with end cover 14′ is provided in the chamber 12 proximate support structure 30. The chuck impedance match network 32 is electrically connected to the chuck assembly 28 through the utility via assembly 31, for example. An external bellows assembly 37 is also provided to allow flexibility in adjusting the height of chuck impedance match network 32 relative to plasma chamber 12, to cover the electrical connection between the chuck match network 32 and the chuck assembly 28 and/or maintain the environment in process chamber 12. The chuck impedance match network 32 is mechanically connected to the chuck assembly 28 through support arm 29 in order to make electrical contact. Hence, a movement of the chuck assembly 28 will transfer to the chuck impedance match network 32. Therefore, the bellows assembly 37 is provided to allow relative movement of the chuck impedance match network assembly 32 relative to the walls of chamber 12 which are fixed while providing a seal to the vacuum inside chamber 12.

The plasma reactor 10 further includes a gas supply system 36 in pneumatic communication with plasma chamber 12 via one or more gas conduits 38 for supplying gas in a regulated manner to form the plasma. Gas supply system 36 can supply one or more gases such as chlorine, hydrogen-bromide, octafluorocyclobutane, various other fluorocarbon compounds or others, and for chemical vapor deposition applications can supply one or more gases such as silane, tungsten-pentafluoride, titanium-tetrachloride, or the like. In one embodiment, a chamber plate (not shown) may be used for example to inject gases in the vicinity and opposite the chuck assembly. The chamber plate may be held by the holding structure 20 or may be also held independently by a different holding system.

Plasma reactor 10 may further include a workpiece handling and robotic system 40 in operative communication with chamber 12 for transporting workpieces to and from workpiece support or chuck assembly 28. The robotic system 40 is arranged in robotic chamber 42 which can be isolated from process chamber 12 by the use of slot valve 44. When the robotic system has finished transporting and depositing the wafer on the chuck assembly 28, the robotic system retracts back to robotic chamber 42 allowing the slot valve 44 to isolate process chamber 12 from robotic chamber 42.

Plasma reactor 10 may further include a main control system 50 to which RF power supply systems 34, gas supply system 36, vacuum system 18, impedance match network 32, impedance match network 26, lift mechanism 39, and workpiece handling and robotic system 40 are electronically connected. In one embodiment, main control system 50 is a computer having a memory unit MU having both a random access memory (RAM) and a read-only memory (ROM), a central processing unit CPU, and a hard disk HD, all in electronic communication. Hard disk HD serves as a secondary computer-readable storage medium, and may be for example, a hard disk drive for storing information corresponding to instructions for controlling plasma reactor 10. The control system 50 may also include a disk drive DD, electronically connected to hard disk HD, memory unit MU and central processing unit CPU, wherein the disk drive is capable of reading and/or writing to a computer-readable medium CRM, such as a floppy disk or compact disc (CD) on which is stored information corresponding to instructions for control system 50 to control the operation of plasma reactor 10.

The chuck assembly 28 and vacuum pump 18 are centered on the same axis. The chuck assembly 28, being held by the support structure 30, is open from all sides, providing a symmetrical path to vacuum pump 18. Therefore, the gas particles all around the chuck assembly 28 and particularly in the plasma region 22 are pumped symmetrically by the vacuum pump 18.

An example of a pumping system that provides symmetrical exhaust of gases can be found in a co-assigned U.S. Pat. No. 6,511,577 entitled “Reduced Impedance Chamber.”

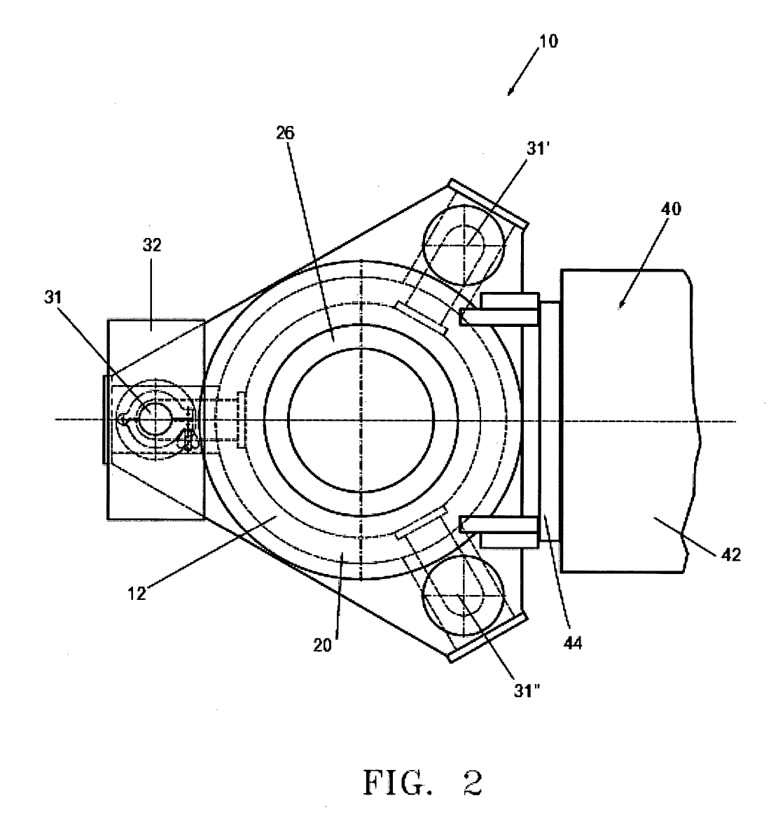

FIG. 2 is a top view of the plasma reactor 10 along the 2-2 line in FIG. 1. FIG. 2 shows electrode impedance match network 26 and chuck impedance match network 32. FIG. 2 also shows the various utility via assemblies 31, 31′ and 31″. The utility via assembly 31 is, for example, arranged to provide RF connection to chuck assembly 28 while utility via assemblies 31′ and 31″ are arranged to provide other utilities, such as for example cooling systems and/or temperature regulation systems, to chuck assembly 28. FIG. 2 also shows a top view of robotic system 40 in operative communication with chamber 12 for transporting workpieces to and from workpiece support or chuck assembly 28 (shown in FIG. 1). The robotic system 40 is enclosed in robotic chamber 42 which can be isolated from process chamber 12 by the use of slot valve 44.

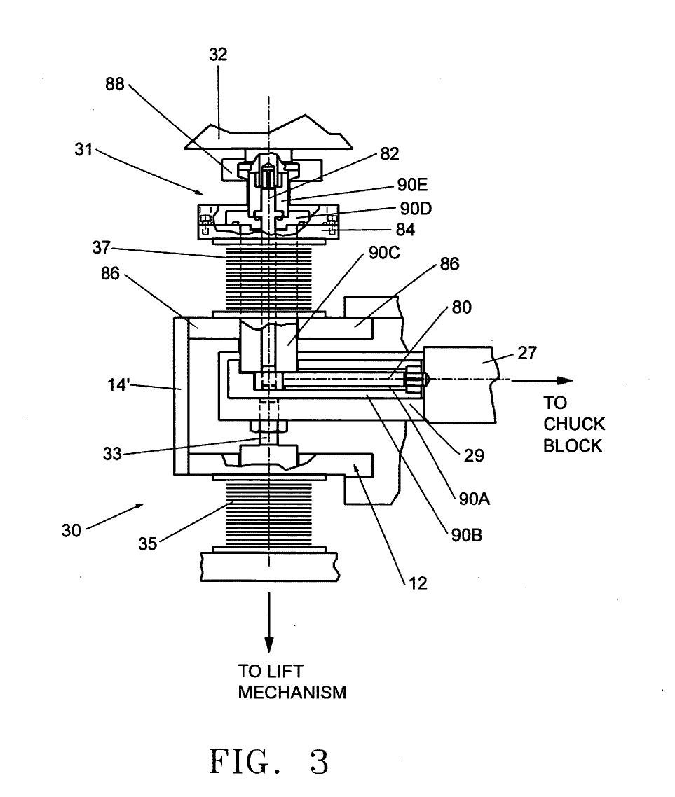

FIG. 3 is a cross-sectional detail of utility via assembly 31 for RF connection to chuck assembly 28. Utility via assembly 31 is constructed and arranged to transmit the RF power to the chuck block 27 of chuck assembly 28 through connectors 80 and 82. Connector 80 electrically couples the chuck block 27 to connector 82 which in turn couples connector 80 to the chuck impedance match network 32.

Since the chamber 12 is grounded, electric insulation is provided to electrically isolate the connectors 80 and 82 from the grounded elements which include the chuck assembly holding arm 29, the utility via assembly housing-ground 84 and the chamber-grounds 86. The electric insulation includes insulators 90A-E. Electric insulators 90A and 90B electrically isolate connector 80 from holding arm 29. Electric insulator 90C electrically isolates connector 82 from chamber-grounds 86, utility via housing-ground 84 and chuck assembly holding arm 29. Electric insulator 90D electrically isolates the connector 82 from utility via housing-ground 84. Finally, electric insulator 90E electrically isolates connector 82 from utility via housing-ground 84 and plasma source clamp 88.

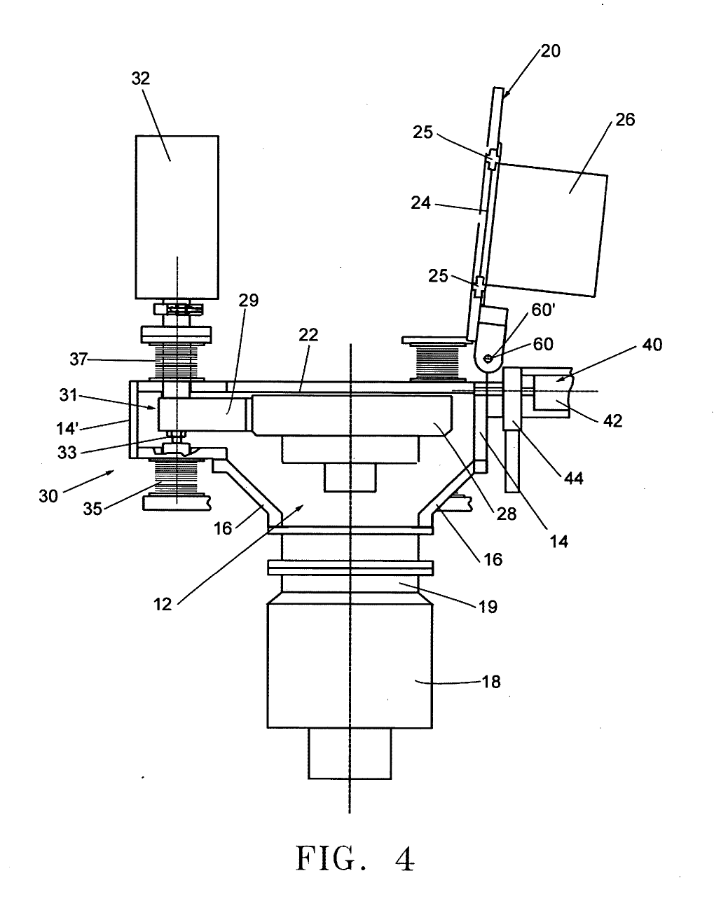

FIG. 4 is a cross-sectional view of the plasma reactor 10 according to another embodiment of the invention. This embodiment of the plasma reactor 10 is similar to the embodiment of the plasma reactor shown in FIG. 1. In this embodiment, the upper holding structure 20 is pivotable around pivot point 60 relative to wall 14 of the plasma process chamber 12, allowing opening of process chamber 12. The upper holding structure 20 can also be pivotable around pivot axis 60′ parallel to a surface of the holding structure 20, for opening of the process chamber 12. Since the upper holding structure 20 holds the electrode assembly 24 and the electrode impedance match network, the electrode assembly 24 with its impedance match network 26 pivot as one assembly, opening up the volume space in the vacuum process chamber 12. In this way, cleaning or other servicing of the process chamber can be made easier to perform. In addition, the pivoting of the upper holding structure 20 allows for easier access to chuck assembly 28 thus facilitating inspecting and servicing of the chuck assembly 28.

In this embodiment, the electrode assembly 24 constitutes at least a portion of the upper holding structure 20 such that the electrode assembly 24 holds the impedance match network 26. The electrode assembly 24 is electrically isolated from the rest of the holding structure 20 by insulator(s) 25.

As shown in FIG. 4, similarly to the embodiment shown in FIG. 1, the chuck assembly 28 is held by support structure 30. This allows freeing the space around the opening in vacuum pump 18 and all around the chuck assembly 28, i.e. the space around plasma region 22 is substantially unobstructed. Therefore, the gas particles all around the chuck assembly 28 and particularly in the plasma region 22 are pumped symmetrically by the vacuum pump 18.

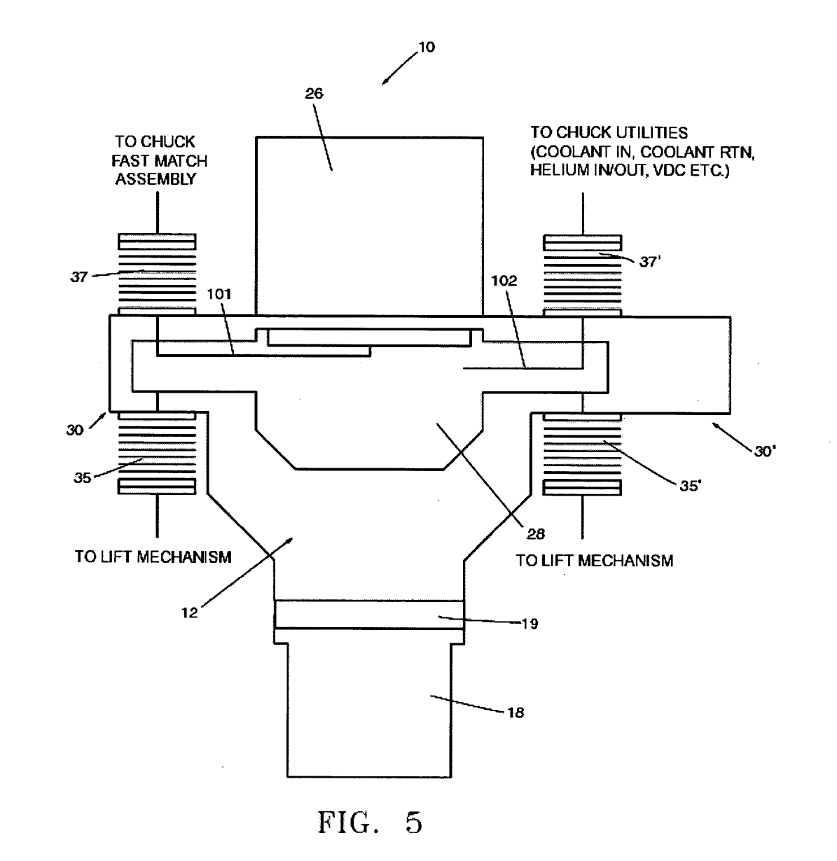

FIG. 5 is a cross-sectional view of a plasma reactor 10 according to another embodiment of the present invention. This embodiment of the plasma reactor includes some of the same components of the previously described embodiments of the plasma reactor. In this embodiment, however, the chuck assembly is supported by support structure 30 and 30′ comprising respectively external bellows assemblies 35 and 35′. The support structures 30 and 30′ are coupled to actuation assemblies such as lift mechanisms (not shown) for raising and lowering the chuck assembly 28. External bellows 35 and 35′ allow for flexibility of movement of support structures 30 and 30′. External bellows assembly 37 and 37′ are also provided to allow adjusting the height of chuck impedance match network and chuck utilities relative to plasma chamber 12 and/or to cover the electrical connections 101 and utilities connections 102 between, respectively, the chuck impedance match network and the chuck assembly, and between the chuck utilities and the chuck assembly 28. In this embodiment, the lift mechanism for the chuck assembly is provided below the chuck assembly 28.

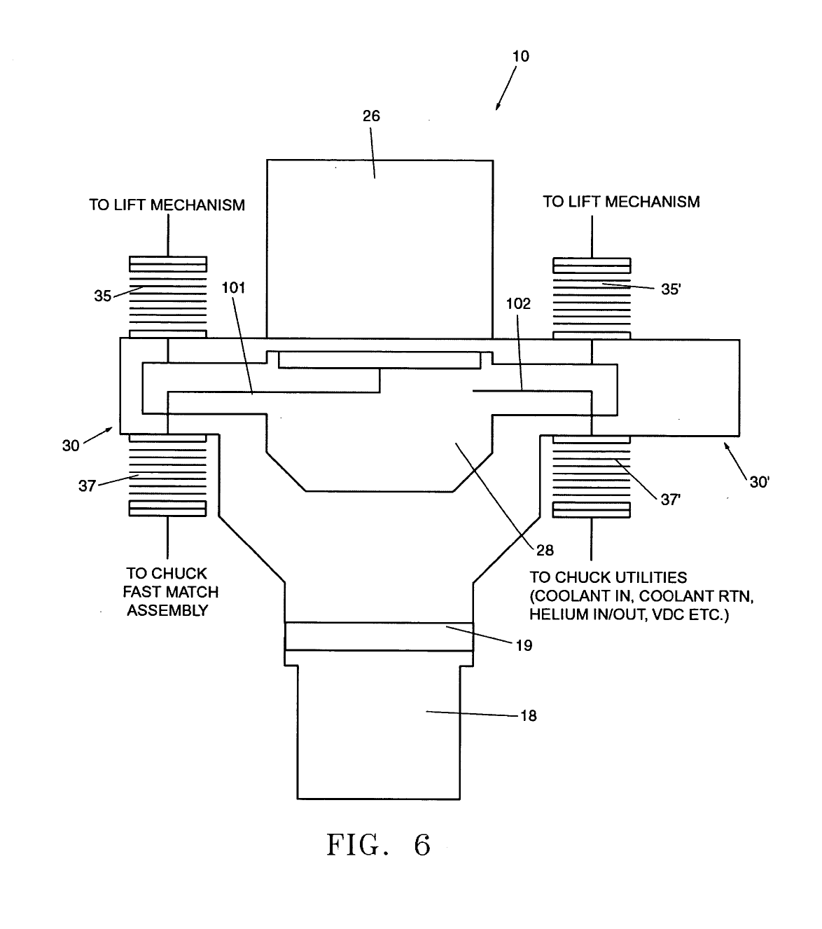

FIG. 6 is a cross-sectional view of a plasma reactor 10 according to yet another embodiment of the present invention. This embodiment of the plasma reactor is similar to the embodiment illustrated in FIG. 5. Similarly to the embodiment illustrated in FIG. 5, the support structures 30 and 30′ are provided with external bellows assemblies 35 and 35′ and are coupled to actuation assemblies such as lift mechanisms (not shown) for raising and lowering the chuck assembly 28. External bellows assembly 37 and 37′ are also provided to allow free movement of the chuck impedance match network and chuck utilities relative to the process chamber, to cover the electrical connections 101 and utilities connections 102 between, respectively, the chuck impedance match network and the chuck assembly, and between the chuck utilities and the chuck assembly 28 and/or maintain the environment in process chamber 12. In this embodiment, however, the lift mechanism for the chuck assembly is provided above chuck assembly 28.

Although the holding structure is shown in the Figures on top of the vacuum chamber (i.e., constituting the top wall of the vacuum chamber), one of ordinary skill in the art would appreciate that the holding structure can be placed, for example, in anyone of the sidewalls or the chamber adapter. Similarly, although the holding structure is shown in the Figures covering the entirety of the upper opening of the vacuum chamber, a holding structure covering only a portion of an opening in the chamber is also within the scope of the present invention. Moreover, any of the above described embodiments can have a pivotable holding structure and any of the above described embodiments can be provided with a lift mechanism that can drive the chuck assembly from the top and/or bottom of the process chamber. The many features and advantages of the present invention are apparent from the detailed specification and thus, it is intended by the appended claims to cover all such features and advantages of the described apparatus which follow the true spirit and scope of the invention.

Furthermore, since numerous modifications and changes will readily occur to those of skill in the art, it is not desired to limit the invention to the exact construction and operation described herein. Moreover, the process and apparatus of the present invention, like related apparatus and processes used in the semiconductor arts tend to be complex in nature and are often best practiced by empirically determining the appropriate values of the operating parameters or by conducting computer simulations to arrive at a best design for a given application. Accordingly, all suitable modifications and equivalents should be considered as falling within the spirit and scope of the invention.

1. A plasma reactor comprising:
a process chamber;
a chuck assembly;
a plasma source assembly;
a holding structure constructed and arranged to hold said plasma source assembly, said holding structure at least partially constitutes a wall of said process chamber; and
a support structure constructed and arranged to support said chuck assembly,
wherein said support assembly is constructed and arranged to raise and lower said chuck assembly relative to said plasma source assembly.

2. A plasma reactor as recited in claim 1, wherein said plasma source assembly is a capacitively coupled plasma (CCP) source assembly.

3. A plasma reactor as recited in claim 2, wherein said capacitively coupled plasma (CCP) source assembly comprises an electrode assembly constructed and arranged adjacent to the chuck assembly, said electrode assembly and said chuck assembly defining a plasma region therebetween.

4. A plasma reactor as recited in claim 1, wherein said plasma source assembly is an inductively coupled plasma (ICP) source assembly.

5. A plasma reactor as recited in claim 4, wherein said inductively coupled plasma source assembly comprises an inductive coil.

6. A plasma reactor as recited in claim 1, wherein said plasma source assembly is an electrostatically shielded radio frequency (ESRF) plasma source assembly.

7. A plasma reactor as recited in claim 6, wherein said electrostatically shielded radio frequency (ESRF) plasma source assembly comprises a coil provided in the vicinity of a said chuck assembly.

8. A plasma reactor as recited in claim 1, wherein said plasma source assembly is an electron cyclotron resonance plasma source assembly.

9. A plasma reactor as recited in claim 1, wherein said plasma source assembly is a helicon plasma source assembly.

10. A plasma reactor as recited in claim 1, further comprising a plasma source impedance match network held by said holding structure.

11. A plasma reactor as recited in claim 10, wherein said plasma source impedance match network is electrically coupled to said plasma source assembly.

12. A plasma reactor as recited in claim 1, further comprising a chuck impedance match network supported by said support structure.

13. A plasma reactor as recited in claim 12, wherein said chuck impedance match network is electrically coupled to said chuck assembly.

14. A plasma reactor as recited in claim 13,
wherein said chuck impedance match network is constructed and arranged to provide radio-frequency bias connection to said chuck assembly.

15. A plasma reactor as recited in claim 1, further comprising:
a utility via assembly constructed and arranged to provide utilities to said chuck assembly.

16. A plasma reactor as recited in claim 15, wherein said utilities include cooling systems and temperature regulating systems.

17. A plasma reactor as recited in claim 1, further comprising:
a gas supply system in communication with said plasma vacuum chamber, said gas supply system being constructed and arranged to supply a gas into said plasma vacuum chamber.

18. A plasma reactor as recited in claim 17, wherein said gas includes at least one of hydrogen-bromide, octafluorocyclobutane, fluorocarbon compounds, silane, tungsten-pentafluoride, and titanium-tetrachloride.

19. A plasma reactor as recited in claim 1, further comprising:
a robotic system in operative communication with said plasma vacuum chamber, said robotic system being constructed and arranged to transport a workpiece to and from the chuck assembly.

20. A plasma reactor as recited in claim 19, further comprising:
a robotic chamber; and
a valve,
wherein said robotic system is arranged in said robotic chamber, said robotic chamber and said vacuum chamber are isolated with said valve.

21. A plasma reactor as recited in claim 1, wherein said vacuum chamber comprises sidewalls and a chamber adapter constructed and arranged to hold a vacuum pump adapted to evacuate gases from said vacuum chamber.

22. A plasma reactor as recited in claim 21, wherein said vacuum pump is a turbo molecular pump (TMP).

23. A plasma reactor as recited in claim 21, wherein said vacuum pump is arranged symmetrically to an axis perpendicular to said chuck assembly, said axis passing through approximately a center of said chuck assembly such that pumping of said gases is symmetrical relative to said axis.

24. A plasma reactor as recited in claim 21, wherein a space around an opening in vacuum pump and around said chuck assembly is substantially unobstructed thereby allowing pumping symmetrically.

25. A plasma reactor as recited in claim 1, further comprising:
a chamber plate constructed and arranged to inject gases in the vicinity and opposite the chuck assembly.

26. A plasma reactor as recited in claim 25, wherein said chamber plate is held by said holding structure.

27. A plasma reactor as recited in claim 1, wherein said chuck assembly is constructed and arranged to hold a workpiece.

28. A plasma reactor as recited in claim 1, wherein said holding structure is constructed and arranged to pivot around a pivot point relative to a wall of said process chamber.

29. A plasma reactor as recited in claim 1, wherein said holding structure is constructed and arranged to pivot around a pivot axis parallel to a surface of said holding structure.

30. A plasma reactor as recited in claim 1, wherein said support structure comprises:
an actuation assembly; and
a support mechanism coupled to said actuation assembly and to said chuck assembly.

31. A plasma reactor as recited in claim 30, wherein said support structure further comprises a bellows assembly positioned around said support mechanism and arranged to allow free movement of said support mechanism relative to said chuck assembly.

32. A plasma a reactor as recited in claim 31, wherein said support mechanism is coupled through said bellows assembly to said actuation assembly and said bellows is external to said process chamber.

33. A plasma reactor as recited in claim 30, wherein said actuation assembly comprises a lift mechanism disposed below said process chamber.

34. A plasma reactor as recited in claim 30, wherein said actuation assembly comprises a lift mechanism disposed above said process chamber.

35. A method for varying the space between a plasma source assembly and a chuck assembly, the plasma source assembly being held by a holding structure and the chuck assembly being held by a support structure, the method comprising:
raising or lowering said chuck assembly relative to said plasma source assembly by using a lift mechanism, said lift mechanism being coupled to said support structure.
